(19) United States
(12) Patent Application Publication
(10) Pub. No.: US 2026/0293693 A1
(43) Pub. Date: Sep. 24, 2026

(54) HIGH-SPEED SIGNAL STABILIZATION IN A COMMON SUBSTRATE

(71) Applicant: Micron Technology, Inc., Boise, ID (US)

(72) Inventors: Kelvin Aik Boo TAN, Singapore (SG); Hong Wan NG, Singapore (SG); Chin Hui CHONG, Singapore (SG); Seng Kim YE, Singapore (SG); See Hiong LEOW, Singapore (SG)

(21) Appl. No.: 19/457,246

(22) Filed: Jan. 23, 2026

Related U.S. Application Data
(60) Provisional application No. 63/776,432, filed on Mar. 24, 2025.

(51) Int. Cl. H10W 44/20; H10B 80/00; H10D 80/20; H10D 80/30; H10W 90/00; H10W 90/10

(52) U.S. Cl. CPC H10W 44/223; H10B 80/00; H10D 80/213; H10D 80/30; H10W 44/206; H10W 90/10; H10W 90/754

(57) ABSTRACT

A device includes a circuit substrate comprising a plurality of signal traces that form a differential pair of signal lines, including a first differential signal line and a second differential signal line; a first die arranged on the circuit substrate, wherein the first die is coupled to the differential pair of signal lines; a second die arranged on the circuit substrate, wherein the second die is coupled to the differential pair of signal lines; a first surface-mounted resistor arranged on the circuit substrate, wherein the first surface-mounted resistor is configured to provide a first jumper connection, between the first die and the second die, along the first differential signal line; and a second surface-mounted resistor arranged on the circuit substrate, wherein the second surface-mounted resistor is configured to provide a second jumper connection, between the first die and the second die, along the second differential signal line.

### CROSS-REFERENCE TO RELATED APPLICATION

This Patent Application claims priority to U.S. Provisional Patent Application No. 63/776,432, filed on Mar. 24, 2025, entitled “HIGH-SPEED SIGNAL STABILIZATION IN A COMMON SUBSTRATE,” and assigned to the assignee hereof. The disclosure of the prior Application is considered part of and is incorporated by reference into this Patent Application.

### TECHNICAL FIELD

The present disclosure generally relates to semiconductor devices, such as memory devices, configured with high-speed signal stabilization in a common substrate.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 shows a device according to one or more implementations.

FIG. 2 is a flowchart of an example method of forming an integrated assembly or a device having high-speed signal stabilization in a common substrate.

### DETAILED DESCRIPTION

In the semiconductor industry, the management of high-speed digital signals is critical, especially in the context of semiconductor packages that may contain varying configurations of dies and die stacks. These packages may utilize differential signaling on a differential pair of signal lines for high-speed signals. In differential signaling, two complementary signals (e.g., a differential signal pair) are transmitted over a pair of wires or signal lines. Any external noise that affects the differential signal typically affects both wires equally. At a receiver, a difference between the two complementary signals is taken, which cancels out common-mode noise (e.g., noise that affects both signals equally). This makes differential signaling more resilient to electromagnetic interference (EMI) and crosstalk compared to single-ended signals. Differential signal pairs create equal and opposite currents that may radiate less electromagnetic energy than single-ended signals. As a result of less electromagnetic energy being radiated, interference with nearby circuits may be reduced and compliance with EMI regulations may be easier to achieve. Moreover, because differential signals are less susceptible to noise and interference, differential signals may allow for higher data rates over longer distances without distortion. Many high-speed interfaces (e.g., PCIe, USB, HDMI, Ethernet, etc.) use differential signaling to maintain signal integrity. Differential signals may also operate at lower voltage levels as compared to single-ended signals, reducing power consumption and increasing switching speed.

However, differential signal lines that are left unused or otherwise inactive can introduce noise and signal integrity issues, potentially affecting the performance of other active signals within a common circuit substrate or at one or more dies connected to the differential signal lines. The current industry approach involves creating different substrate designs for low and high die stack configurations, which can be resource-intensive and costly. Additionally, the use of jumper wires to mitigate floating high-speed signal noise presents significant risks, including wire swag, wire shorting (e.g., when jumper wires come in contact with each other), and non-stick on lead (NSOL) defects. These risks can lead to higher defective parts per million (dppm) yields, which drive up manufacturing costs and/or lead to more unreliable devices. For example, designs that use jumper wires may have 2,000 dppm. The industry trend has been to either split the substrate design based on die stack density or to leave unused pins unconnected, allowing the unused pins to float, which does not adequately address the signal integrity challenges and can exacerbate the management complexity of multiple substrate designs.

Some implementations described herein provide circuitry for high-speed signal stabilization in a common circuit substrate that connects two dies by a differential pair of signal lines (e.g., two differential signal lines). For example, the common circuit substrate may include a plurality of signal traces forming the differential pair of signal lines, and surface-mounted resistors (e.g., zero-ohm equivalent resistors) that form jumper connections along the differential pair of signal lines. The surface-mounted resistors connect the differential signal lines to power and ground planes, mitigating signal noise toggling from unused high-speed signal traces.

In some aspects, the differential pair of signal lines includes a first differential signal line that is a positive signal line and a second differential signal line that is a negative signal line. A device may include two dies, such as a memory controller die and a memory die, arranged on the common circuit substrate and coupled to the differential pair of signal lines. The surface-mounted resistors connect controller die terminals of the memory controller die to memory die terminals of the memory die along the differential pair of signal lines.

Additionally, for the first differential signal line, one terminal of a first surface-mounted resistor corresponds to the first differential signal line and provides a jumper connection along the first differential signal line. Thus, the first surface-mounted resistor connects the two dies along the first differential signal line. For the second differential signal line, one terminal of a second surface-mounted resistor corresponds to the second differential signal line and provides a jumper connection along the second differential signal line. Thus, the second surface-mounted resistor connects the two dies along the second differential signal line. Additionally, for the first differential signal line, another terminal of the first surface-mounted resistor is connected to the power plane, and, for the second differential signal line, another terminal of the second surface-mounted resistor is connected to the ground plane. The power plane and ground plane connections mitigate signal noise on the differential pair of signal lines.

Moreover, using the surface-mounted resistors as jumpers instead of jumper wires significantly reduces the risk or eliminates the risk of wire swag, wire shorting, and non-stick on lead problems. For example, using the surface-mounted resistors as jumpers may reduce a dppm yield to zero or substantially zero, resulting in significantly higher product yields that satisfy operational requirements.

In this way, one or more implementations described herein may address the problem of managing high-speed digital signals in semiconductor packages with varying die stack configurations. By using zero-ohm resistors as jumper connections on a common substrate, the design can be uniformly applied to different types of semiconductor packages and varying die stack configurations. In addition, the design effectively eliminates the risks associated with jumper wires, such as wire swag, shorting, and non-stick on lead issues. This approach also reduces the dppm amount, which is critical in high-quality requirement applications, such as automotive electronics.

In this way, one or more implementations described herein may conserve resources by eliminating the need for different substrate designs for low and high die stack configurations, leading to cost savings in design and manufacturing processes. The integration with existing surface mount technology (SMT) lines optimizes production efficiency and reduces the necessity for additional equipment or specialized training. By mitigating wirebond swag, shorting risk, and non-stick on lead risk, the reliability of the device is enhanced. Consequently, the design for varying die stack configurations simplifies inventory management and reduces the resource overhead associated with the production of multiple product configurations. This technical benefit is particularly significant in the context of large-scale manufacturing, where even minor efficiency gains can translate into substantial resource conservation. By improving the quality and/or the reliability of the device, an amount of resources used to produce the device (e.g., raw materials, semiconductor manufacturing tools, labor, and/or computing resources) is reduced.

To further enhance signal stability, in some implementations, sensitive high-speed digital lines are routed directly to SMT pads on the circuit substrate. This routing ensures that the zero-ohm resistors, acting as jumper connections, effectively stabilize the high-speed signals by connecting the unused differential pair signal lines to the appropriate power and ground planes. The routing to SMT pads facilitates precise control over signal integrity and reduces potential noise interference.

Some implementations described herein may also eliminate the risks associated with high wire shorting and wire swag by providing a single substrate design solution applicable to both low die stack and high die stack configurations. This approach may mitigate floating high-speed signal noise from dummy bond fingers, which may be used in high-density die stacks. This unified substrate design may impact the manufacturing of millions of packages, streamlining production and reducing defect rates.

In some implementations, the surface-mounted resistors can be attached or removed during the assembly line to switch the connection on or off. This flexibility allows for optimization of the signal connection based on the specific requirements of the package at hand. When it is necessary to establish a connection, the surface-mounted resistors can be mounted to the circuit substrate. Conversely, when it is desirable to break the connection, the resistors can be removed during the assembly process. This feature provides an adaptable solution for managing high-speed signal pathways within a package assembly.

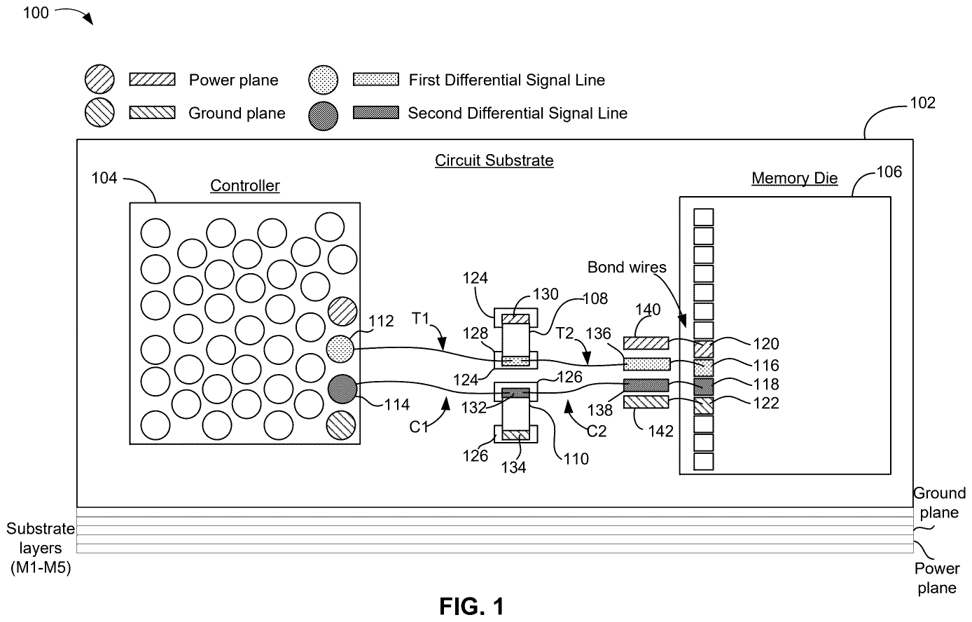

FIG. 1 shows a device 100 according to one or more implementations. The device 100 may be a packaged device that includes two or more dies (e.g., semiconductor dies). In some implementations, the device 100 may be a memory device that houses memory components, such as a memory controller and one or more memory dies that are controlled or otherwise managed by the memory controller.

In some implementations, the device 100 may include any type of device or system that includes two or more semiconductor dies. For example, the device 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the device 100 may be referred to as a semiconductor package, an assembly, a semiconductor device assembly, or an integrated assembly.

As shown in FIG. 1, the device 100 may include a circuit substrate 102, a first die 104, and a second die 106. The circuit substrate 102 may be a printed circuit board (PCB) or another type of chip carrier. The circuit substrate 102 may include a plurality of stacked substrate layers, including conductive layers (e.g., metal layers) and non-conductive layers (e.g., dielectric layers). In some implementations, the conductive layers may include a first metal layer (e.g., metal layer 1 or M1) as a top metal layer, a second metal layer (e.g., metal layer 2 or M2) as a first inner layer, a third metal layer (e.g., metal layer 3 or M3) as a second inner layer, and so on. A non-conductive layer may be arranged between successive metal layers, and metal layers may be connected by vias extending through the non-conductive layers.

The circuit substrate 102 includes a power plane and a ground plane that are provided by different conductive layers. The power plane may be formed by a metal layer dedicated to distributing power (common collector voltage (VCC), drain voltage (VDD), etc.) to different components. The ground plane may be formed by a different metal layer that serves as a reference voltage (0V) or ground voltage for the different components. In some implementations, metal layers 1, 2, and 3 may be used as signal layers, metal layer 4 may be used as a ground plane, and metal layer 5 may be used as a power plane. Each metal layer may be electrically coupled to one or more pads or bond fingers arranged on an upper surface of the circuit substrate 102 by respective conductive vias.

The first die 104 and the second die 106 may include any type of circuit, such as an analog circuit, a digital circuit, a controller (e.g., a microcontroller), a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). In some examples, the first die 104 is a memory controller die and the second die 106 is a memory die, such as a NAND memory die. The first die 104 and the second die 106 may be mounted on or otherwise disposed on a surface of the circuit substrate 102. Although the device 100 is shown as including one second die 106 as an example, the device 100 may include a different number of second dies 106, such as two or more second dies 106 arranged in a vertical die stack.

The circuit substrate 102 has a plurality of signal traces that form a differential pair of signal lines that are connected to the first die 104 and the second die 106. For example, metal layers 1, 2, and/or 3 may be used for routing the plurality of signal traces through the circuit substrate 102. The differential pair of signal lines includes a first differential signal line having a first segment T1 and a second segment T2. The differential pair of signal lines further include a second differential signal line having a first segment C1 and a second segment C2. The first segment T1 of the first differential signal line, the first segment C1 of the second differential signal line, the second segment T2 of the first differential signal line, and the second segment C2 of the second differential signal line are each at least partially routed through an interior of the circuit substrate 102 (e.g., in one or more metal layers).

The differential pair of signal lines may be complimentary signal lines that are configurable to transmit a high-speed differential signal. For example, in some implementations, the first differential signal line T1, T2 is a positive signal line and the second differential signal line C1, C2 is a negative signal line. In some applications, depending on the type of dies being used, the differential pair of signal lines may not be used to carry useful signals and may be inactive. In other words, the plurality of signal traces may be floating signal traces, and the first differential signal line T1, T2 and the second differential signal line C1, C2 may be floating signal lines in a floating state. When the differential pair of signal lines are floating, the differential pair of signal lines may be susceptible to signal noise (e.g., signal noise toggling) that can interfere with other signals or one or more operations of the first die 104 and/or the second die 106.

The first die 104 may include a first die terminal 112 (e.g., a first controller die terminal) coupled to the first segment T1 of the first differential signal line, and a second die terminal 114 (e.g., a second controller die terminal) coupled to the first segment C1 of the second differential signal line. The first die 104 may include additional terminals, including terminals connected to the power plane and the ground plane of the circuit substrate 102 for powering the first die 104.

The second die 106 may include a third die terminal 116 (e.g., a first memory die terminal) coupled to the second segment T2 of the first differential signal line, and a fourth die terminal 118 (e.g., a second memory die terminal) coupled to the second segment C2 of the second differential signal line. In addition, the second die 106 may include a fifth die terminal 120 (e.g., a third memory die terminal) coupled to the power plane of the circuit substrate 102, and a sixth die terminal 122 (e.g., a fourth memory die terminal) coupled to the ground plane of the circuit substrate 102.

The first die terminal 112, the second die terminal 114, the third die terminal 116, and the fourth die terminal 118 (e.g., the first controller die terminal, the second controller die terminal, the first memory die terminal, and the second memory die terminal) may be high-speed differential signal terminals configured in an inactive state. In other words, the first die terminal 112, the second die terminal 114, the third die terminal 116, and the fourth die terminal 118 may be in a floating state. Hence, the first differential signal line T1, T2 and the second differential signal line C1, C2 may be floating signal lines in a floating state.

The device 100 includes a first surface-mounted resistor 108 arranged on the circuit substrate 102. The first surface-mounted resistor 108 is coupled to the first segment T1 of the first differential signal line and the second segment T2 of the first differential signal line for connecting the first die terminal 112 and the third die terminal 116. The device 100 further includes a second surface-mounted resistor 110 arranged on the circuit substrate 102. The second surface-mounted resistor 110 is coupled to the first segment C1 of the second differential signal line and the second segment C2 of the second differential signal line for connecting the second die terminal 114 and the fourth die terminal 118. The first surface-mounted resistor 108 and the second surface-mounted resistor 110 may be zero-ohm equivalent resistors (e.g., zero-ohm resistors) that have substantially zero resistance between opposing resistor terminals. Thus, the first surface-mounted resistor 108 and the second surface-mounted resistor 110 are configured to reduce signal noise (e.g., signal noise toggling) on the differential pair of signal lines.

The device 100 may include a first pair of component pads 124 arranged on the circuit substrate 102. The first surface-mounted resistor 108 may be surface mounted to the circuit substrate 102 via the first pair of component pads 124. For example, each resistor terminal of the first surface-mounted resistor 108 may be mounted to a respective component pad or the first pair of component pads 124. The device 100 may further include a second pair of component pads 126 arranged on the circuit substrate 102. The second surface-mounted resistor 110 may be surface mounted to the circuit substrate 102 via the second pair of component pads 126. For example, each resistor terminal of the second surface-mounted resistor 110 may be mounted to a respective component pad of the second pair of component pads 126.

The first surface-mounted resistor 108 provides a first jumper connection between the first segment T1 of the first differential signal line and the second segment T2 of the first differential signal line. In particular, the first surface-mounted resistor 108 includes a first resistor terminal 128 coupled to the first segment T1 of the first differential signal line and to the second segment T2 of the first differential signal line; and a second resistor terminal 130 coupled to the power plane (e.g., a positive supply connection) of the circuit substrate 102. In some implementations, the first segment T1 of the first differential signal line and the second segment T2 of the first differential signal line may be coupled to the component pad 124 corresponding to the first resistor terminal 128. In some implementations, the component pad 124 corresponding to the second resistor terminal 130 may be coupled to the power plane by one or more traces or vias of the circuit substrate 102, thereby connecting the second resistor terminal 130 to the power plane.

The second surface-mounted resistor 110 provides a second jumper connection between the first segment C1 of the second differential signal line and the second segment C2 of the second differential signal line. In particular, the second surface-mounted resistor 110 includes a third resistor terminal 132 coupled to the first segment C1 of the second differential signal line and to the second segment C2 of the second differential signal line; and a fourth resistor terminal 134 coupled to the ground plane (e.g., a ground connection) of the circuit substrate 102. In some implementations, the first segment C1 of the second differential signal line and the second segment T2 of the second differential signal line may be coupled to the component pad 126 corresponding to the third resistor terminal 132. In some implementations, the component pad 126 corresponding to the fourth resistor terminal 134 may be coupled to the ground plane by one or more traces or vias of the circuit substrate 102, thereby connecting the fourth resistor terminal 134 to the ground plane.

Based on the respective connections to the first resistor terminal 128, the second resistor terminal 130, the third resistor terminal 132, and the fourth resistor terminal 134, the first surface-mounted resistor 108 and the second surface-mounted resistor 110 reduce signal noise (e.g., signal noise toggling) on the differential pair of signal lines. This specific configuration ensures that any floating signal lines are properly terminated, further reducing noise and enhancing the stability of the high-speed differential lines within the circuit substrate 102.

In some implementations, the first segment T1 of the first differential signal line comprises two ends respectively coupled to the first die terminal 112 and the first resistor terminal 128, the second segment T2 of the first differential signal line comprises two ends respectively coupled to the first resistor terminal 128 and the third die terminal 116, wherein the first segment C1 of the second differential signal line comprises two ends respectively coupled to the second die terminal 114 and the third resistor terminal 132, and the second segment C2 of the second differential signal line comprises two ends respectively coupled to the third resistor terminal 132 and the fourth die terminal 118. Accordingly, the first resistor terminal 128 provides a first jumper connection for the first segment T1 of the first differential signal line and the second segment T2 of the first differential signal line. Additionally, the third resistor terminal 132 provides a second jumper connection for the first segment C1 of the second differential signal line and the second segment C2 of the second differential signal line.

The device 100 may further include a plurality of surface-mounted bond fingers, including a first surface-mounted bond finger 136, a second surface-mounted bond finger 138, a third surface-mounted bond finger 140, a fourth surface-mounted bond finger 142. These surface-mounted bond fingers are arranged on the circuit substrate 102. The first surface-mounted bond finger 136 may be electrically coupled to the second segment T2 of the first differential signal line and to the third die terminal 116 for connecting the first differential signal line to the second die 106. The first surface-mounted bond finger 136 may be connected to the third die terminal 116 by a first bond wire. The second surface-mounted bond finger 138 may be electrically coupled to the second segment C2 of the second differential signal line and to the fourth die terminal 118 for connecting the second differential signal line to the second die 106. The second surface-mounted bond finger 138 may be connected to the fourth die terminal 118 by a second bond wire. Additionally, the third surface-mounted bond finger 140 may be electrically coupled to the power plane of the circuit substrate 102 and to the fifth die terminal 120. The third surface-mounted bond finger 140 may be connected to the fifth die terminal 120 by a third bond wire. Additionally, the fourth surface-mounted bond finger 142 may be electrically coupled to the ground plane of the circuit substrate 102 and to the sixth die terminal 122. The fourth surface-mounted bond finger 142 may be connected to the sixth die terminal 122 by a fourth bond wire. Signal noise may come from or originate from the first surface-mounted bond finger 136 and/or the second surface-mounted bond finger 138.

The first surface-mounted resistor 108 and the second surface-mounted resistor 110, being zero-ohm equivalent resistors with the connections described elsewhere herein, are configured to reduce the signal noise, on the differential pair of signal lines, from the first surface-mounted bond finger 136 and/or the second surface-mounted bond finger 138. As a result, the first surface-mounted resistor 108 and the second surface-mounted resistor 110 may make the differential pair of signal lines more stable. Moreover, the first surface-mounted resistor 108 and the second surface-mounted resistor 110 reduce or eliminate the risks associated with jumper wires, such as wire swag, wire shorting, and non-stick on lead issues. Thus, the first surface-mounted resistor 108 and the second surface-mounted resistor 110 may reduce the defective dppm yield, and increase overall total product yield. For example, using the first surface-mounted resistor 108 and the second surface-mounted resistor 110 as jumpers, as described herein, may reduce a dppm yield to zero or substantially zero, resulting in significantly higher product yields that satisfy operational requirements. Thus, using the first surface-mounted resistor 108 and the second surface-mounted resistor 110 as jumpers, as described herein, reduces manufacturing costs and enhances the reliability of the device 100.

As indicated above, FIG. 1 is provided as an example. Other examples may differ from what is described with regard to FIG. 1. For example, in some implementations, the signal lines may be independent signal lines (e.g., non-differential signal lines) that are not dependent on or designed for differential signaling. Alternatively, the signal lines may correspond to differential signal lines of different differential pairs of signal lines that are used for transmitting separate differential signals. Thus, the signal lines may be differential signal lines, but may or may not form a differential pair of signal lines that are used together for transmitting a differential signal.

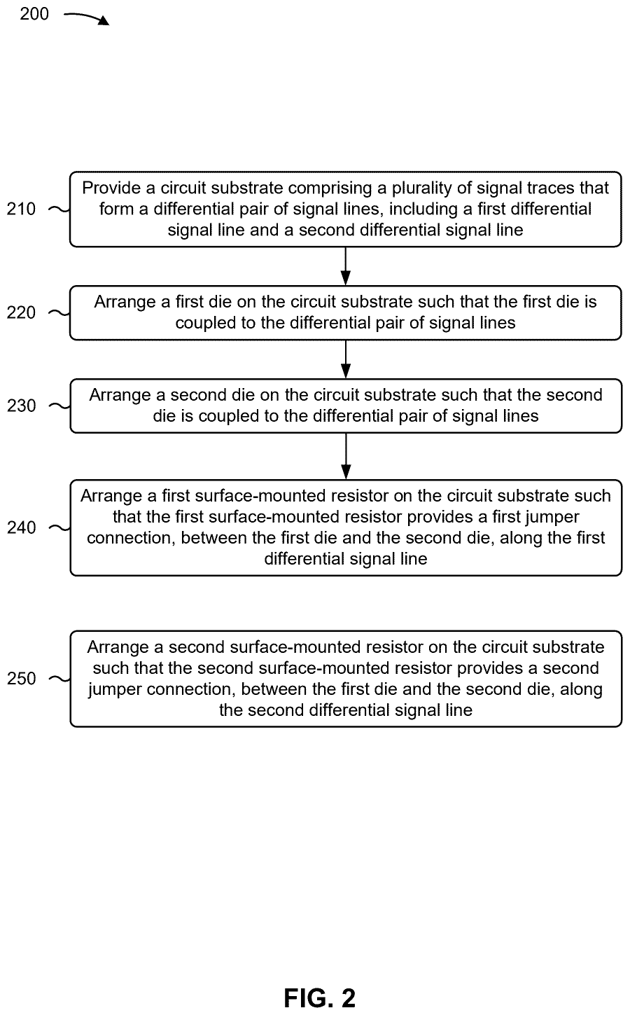

FIG. 2 is a flowchart of an example method 200 of forming an integrated assembly or a device (e.g., memory device) having high-speed signal stabilization in a common substrate. In some implementations, one or more process blocks of FIG. 2 may be performed by various semiconductor manufacturing equipment, device assembly manufacturing equipment, and/or package assembly manufacturing equipment.

As shown in FIG. 2, the method 200 may include providing a circuit substrate comprising a plurality of signal traces that form a differential pair of signal lines, including a first differential signal line and a second differential signal line (block 210). As further shown in FIG. 2, the method 200 may include arranging a first die on the circuit substrate such that the first die is coupled to the differential pair of signal lines (block 220). As further shown in FIG. 2, the method 200 may include arranging a second die on the circuit substrate such that the second die is coupled to the differential pair of signal lines (block 230). As further shown in FIG. 2, the method 200 may include arranging a first surface-mounted resistor on the circuit substrate such that the first surface-mounted resistor provides a first jumper connection, between the first die and the second die, along the first differential signal line (block 240). As further shown in FIG. 2, the method 200 may include arranging a second surface-mounted resistor on the circuit substrate such that the second surface-mounted resistor provides a second jumper connection, between the first die and the second die, along the second differential signal line (block 250). The first surface-mounted resistor and the second surface-mounted resistor may be zero-ohm equivalent resistors. Additionally, or alternatively, the first differential signal line and the second differential signal line may be floating signal lines. Additionally, or alternatively, the first surface-mounted resistor and the second surface-mounted resistor may be configured to reduce signal noise on the differential pair of signal lines, thereby stabilizing the differential pair of signal lines.

The method 200 may include additional aspects, such as any single aspect or any combination of aspects described below and/or in connection with one or more other methods described elsewhere herein.

Although FIG. 2 shows example blocks of the method 200, in some implementations, the method 200 may include additional blocks, fewer blocks, different blocks, or differently arranged blocks than those depicted in FIG. 2. In some implementations, the method 200 may include forming the device 100, an integrated assembly that includes the device 100, any part described herein of the device 100, and/or any part described herein of an integrated assembly that includes the device 100. For example, the method 200 may include forming one or more of parts 102, 104, 106, 108, 110, 124, 126, 136, 138, 140, and/or 142.

In some implementations, a memory device includes a circuit substrate comprising a plurality of signal traces that form signal lines, wherein the signal lines include a first signal line having a first segment and a second segment, and a second signal line having a first segment and a second segment; a memory controller die arranged on, and electrically coupled to, the circuit substrate, wherein the memory controller die comprises: a first controller die terminal coupled to the first segment of the first signal line; and a second controller die terminal coupled to the first segment of the second signal line; a NAND memory die arranged on, and electrically coupled to, the circuit substrate, wherein the NAND memory die comprises: a first memory die terminal coupled to the second segment of the first signal line; and a second memory die terminal coupled to the second segment of the second signal line; a first zero-ohm resistor coupled to the first segment of the first signal line and the second segment of the first signal line for connecting the first controller die terminal and the first memory die terminal; and a second zero-ohm resistor coupled to the first segment of the second signal line and the second segment of the second signal line for connecting the second controller die terminal and the second memory die terminal.

In some implementations, a device includes a circuit substrate comprising a plurality of signal traces that form signal lines, wherein the signal lines include a first signal line having a first segment and a second segment, and a second signal line having a first segment and a second segment; a first die arranged on, and electrically coupled to, the circuit substrate, wherein the first die comprises: a first die terminal coupled to the first segment of the first signal line; and a second die terminal coupled to the first segment of the second signal line; a second die arranged on, and electrically coupled to, the circuit substrate, wherein the second die comprises: a third die terminal coupled to the second segment of the first signal line; and a fourth die terminal coupled to the second segment of the second signal line; a first surface-mounted resistor arranged on the circuit substrate, wherein the first surface-mounted resistor is coupled to the first segment of the first signal line and the second segment of the first signal line for connecting the first die terminal and the third die terminal; and a second surface-mounted resistor arranged on the circuit substrate, wherein the second surface-mounted resistor is coupled to the first segment of the second signal line and the second segment of the second signal line for connecting the second die terminal and the fourth die terminal, wherein the first surface-mounted resistor and the second surface-mounted resistor are configured to reduce signal noise on the signal lines.

In some implementations, a device includes a circuit substrate comprising a plurality of signal traces that form a signal line; a first die arranged on the circuit substrate, wherein the first die is coupled to the signal line; a second die arranged on the circuit substrate, wherein the second die is coupled to the signal line; and a first surface-mounted resistor arranged on the circuit substrate, wherein the first surface-mounted resistor is configured to provide a first jumper connection, between the first die and the second die, along the signal line; and wherein the first surface-mounted resistor is a zero-ohm equivalent resistor, wherein the first signal line is a floating signal line, and wherein the first surface-mounted resistor is configured to reduce signal noise on the signal line.

In some implementations, a memory device includes a circuit substrate comprising a plurality of signal traces that form a differential pair of signal lines, wherein the differential pair of signal lines includes a first differential signal line having a first segment and a second segment, and a second differential signal line having a first segment and a second segment; a memory controller die arranged on, and electrically coupled to, the circuit substrate, wherein the memory controller die comprises: a first controller die terminal coupled to the first segment of the first differential signal line; and a second controller die terminal coupled to the first segment of the second differential signal line; a NAND memory die arranged on, and electrically coupled to, the circuit substrate, wherein the NAND memory die comprises: a first memory die terminal coupled to the second segment of the first differential signal line; and a second memory die terminal coupled to the second segment of the second differential signal line; a first zero-ohm resistor coupled to the first segment of the first differential signal line and the second segment of the first differential signal line for connecting the first controller die terminal and the first memory die terminal; and a second zero-ohm resistor coupled to the first segment of the second differential signal line and the second segment of the second differential signal line for connecting the second controller die terminal and the second memory die terminal.

In some implementations, a device includes a circuit substrate comprising a plurality of signal traces that form a differential pair of signal lines, wherein the differential pair of signal lines includes a first differential signal line having a first segment and a second segment, and a second differential signal line having a first segment and a second segment; a first die arranged on, and electrically coupled to, the circuit substrate, wherein the first die comprises: a first die terminal coupled to the first segment of the first differential signal line; and a second die terminal coupled to the first segment of the second differential signal line; a second die arranged on, and electrically coupled to, the circuit substrate, wherein the second die comprises: a third die terminal coupled to the second segment of the first differential signal line; and a fourth die terminal coupled to the second segment of the second differential signal line; a first surface-mounted resistor arranged on the circuit substrate, wherein the first surface-mounted resistor is coupled to the first segment of the first differential signal line and the second segment of the first differential signal line for connecting the first die terminal and the third die terminal; and a second surface-mounted resistor arranged on the circuit substrate, wherein the second surface-mounted resistor is coupled to the first segment of the second differential signal line and the second segment of the second differential signal line for connecting the second die terminal and the fourth die terminal, wherein the first surface-mounted resistor and the second surface-mounted resistor are configured to reduce signal noise on the differential pair of signal lines.

In some implementations, a device includes a circuit substrate comprising a plurality of signal traces that form a differential pair of signal lines, wherein the differential pair of signal lines includes a first differential signal line and a second differential signal line; a first die arranged on the circuit substrate, wherein the first die is coupled to the differential pair of signal lines; a second die arranged on the circuit substrate, wherein the second die is coupled to the differential pair of signal lines; a first surface-mounted resistor arranged on the circuit substrate, wherein the first surface-mounted resistor is configured to provide a first jumper connection, between the first die and the second die, along the first differential signal line; and a second surface-mounted resistor arranged on the circuit substrate, wherein the second surface-mounted resistor is configured to provide a second jumper connection, between the first die and the second die, along the second differential signal line, wherein the first surface-mounted resistor and the second surface-mounted resistor are zero-ohm equivalent resistors, wherein the first differential signal line and the second differential signal line are floating signal lines, and wherein the first surface-mounted resistor and the second surface-mounted resistor are configured to reduce signal noise on the differential pair of signal lines.

In some implementations, a method of manufacturing a device includes providing a circuit substrate comprising a plurality of signal traces that form a differential pair of signal lines, wherein the differential pair of signal lines includes a first differential signal line and a second differential signal line; arranging a first die on the circuit substrate such that the first die is coupled to the differential pair of signal lines; arranging a second die on the circuit substrate such that the second die is coupled to the differential pair of signal lines; arranging a first surface-mounted resistor on the circuit substrate such that the first surface-mounted resistor provides a first jumper connection, between the first die and the second die, along the first differential signal line; and arranging a second surface-mounted resistor on the circuit substrate such that the second surface-mounted resistor provides a second jumper connection, between the first die and the second die, along the second differential signal line, wherein the first surface-mounted resistor and the second surface-mounted resistor are zero-ohm equivalent resistors, wherein the first differential signal line and the second differential signal line are floating signal lines, and wherein the first surface-mounted resistor and the second surface-mounted resistor are configured to reduce signal noise on the differential pair of signal lines.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
a circuit substrate comprising a plurality of signal traces that form signal lines,
wherein the signal lines include a first signal line having a first segment and a second segment, and a second signal line having a first segment and a second segment;
a memory controller die arranged on, and electrically coupled to, the circuit substrate, wherein the memory controller die comprises:
a first controller die terminal coupled to the first segment of the first signal line; and
a second controller die terminal coupled to the first segment of the second signal line;
a NAND memory die arranged on, and electrically coupled to, the circuit substrate, wherein the NAND memory die comprises:
a first memory die terminal coupled to the second segment of the first signal line; and
a second memory die terminal coupled to the second segment of the second signal line;
a first zero-ohm resistor coupled to the first segment of the first signal line and the second segment of the first signal line for connecting the first controller die terminal and the first memory die terminal; and
a second zero-ohm resistor coupled to the first segment of the second signal line and the second segment of the second signal line for connecting the second controller die terminal and the second memory die terminal.

2. The memory device of claim 1, wherein the first zero-ohm resistor comprises:
a first resistor terminal coupled to the first segment of the first signal line and the second segment of the first signal line; and
a second resistor terminal coupled to a power plane of the circuit substrate, and
wherein the second zero-ohm resistor comprises:
a third resistor terminal coupled to the first segment of the second signal line and the second segment of the second signal line; and
a fourth resistor terminal coupled to a ground plane of the circuit substrate.

3. The memory device of claim 2, wherein the first segment of the first signal line comprises two ends respectively coupled to the first controller die terminal and the first resistor terminal,
wherein the second segment of the first signal line comprises two ends respectively coupled to the first resistor terminal and the first memory die terminal,
wherein the first segment of the second signal line comprises two ends respectively coupled to the second controller die terminal and the third resistor terminal, and
wherein the second segment of the second signal line comprises two ends respectively coupled to the third resistor terminal and the second memory die terminal.

4. The memory device of claim 2, wherein the first resistor terminal provides a first jumper connection for the first segment of the first signal line and the second segment of the first signal line, and
wherein the third resistor terminal provides a second jumper connection for the first segment of the second signal line and the second segment of the second signal line.

5. The memory device of claim 2, wherein the NAND memory die comprises:
a third memory die terminal coupled to the power plane of the circuit substrate; and
a fourth memory die terminal coupled to the ground plane of the circuit substrate.

6. The memory device of claim 1, wherein the signal lines are a differential pair of signal lines, and wherein the first signal line is a positive signal line of the differential pair of signal lines and the second signal line is a negative signal line of the differential pair of signal lines.

7. The memory device of claim 1, wherein the plurality of signal traces are floating signal traces.

8. The memory device of claim 1, wherein the signal lines are a differential pair of signal lines, and wherein the first controller die terminal, the second controller die terminal, the first memory die terminal, and the second memory die terminal are high-speed differential signal terminals configured in an inactive state.

9. The memory device of claim 1, wherein the signal lines are a differential pair of signal lines, and wherein the differential pair of signal lines are configurable to transmit a high-speed differential signal.

10. The memory device of claim 1, wherein the first segment of the first signal line, the first segment of the second signal line, the second segment of the first signal line, and the second segment of the second signal line are each at least partially routed through an interior of the circuit substrate.

11. The memory device of claim 1, further comprising:
a first pair of component pads arranged on the circuit substrate, wherein the first zero-ohm resistor is surface mounted to the circuit substrate via the first pair of component pads; and
a second pair of component pads arranged on the circuit substrate, wherein the second zero-ohm resistor is surface mounted to the circuit substrate via the second pair of component pads.

12. The memory device of claim 1, wherein the signal lines are a differential pair of signal lines, and wherein the first zero-ohm resistor and the second zero-ohm resistor are configured to mitigate signal noise toggling on the differential pair of signal lines.

13. The memory device of claim 1, further comprising:
a first surface-mounted bond finger electrically coupled to the second segment of the first signal line and to the first memory die terminal for connecting the first signal line to the NAND memory die; and
a second surface-mounted bond finger electrically coupled to the second segment of the second signal line and to the second memory die terminal for connecting the second signal line to the NAND memory die.

14. The memory device of claim 1, wherein the first zero-ohm resistor and the second zero-ohm resistor are zero-ohm equivalent resistors having substantially zero resistance.

15. A device, comprising:
a circuit substrate comprising a plurality of signal traces that form signal lines,
wherein the signal lines include a first signal line having a first segment and a second segment, and a second signal line having a first segment and a second segment;
a first die arranged on, and electrically coupled to, the circuit substrate, wherein the first die comprises:
a first die terminal coupled to the first segment of the first signal line; and
a second die terminal coupled to the first segment of the second signal line;
a second die arranged on, and electrically coupled to, the circuit substrate, wherein the second die comprises:
a third die terminal coupled to the second segment of the first signal line; and
a fourth die terminal coupled to the second segment of the second signal line;
a first surface-mounted resistor arranged on the circuit substrate, wherein the first surface-mounted resistor is coupled to the first segment of the first signal line and the second segment of the first signal line for connecting the first die terminal and the third die terminal; and
a second surface-mounted resistor arranged on the circuit substrate, wherein the second surface-mounted resistor is coupled to the first segment of the second signal line and the second segment of the second signal line for connecting the second die terminal and the fourth die terminal,
wherein the first surface-mounted resistor and the second surface-mounted resistor are configured to reduce signal noise on the signal lines.

16. The device of claim 15, wherein the first surface-mounted resistor and the second surface-mounted resistor are zero-ohm equivalent resistors.

17. The device of claim 15, wherein the first surface-mounted resistor provides a first jumper connection between the first segment of the first signal line and the second segment of the first signal line, and
wherein the second surface-mounted resistor provides a second jumper connection between the first segment of the second signal line and the second segment of the second signal line.

18. The device of claim 15, wherein the first surface-mounted resistor comprises:
a first resistor terminal coupled to the first segment of the first signal line and to the second segment of the first signal line; and
a second resistor terminal coupled to a positive supply connection of the circuit substrate, and
wherein the second surface-mounted resistor comprises:
a third resistor terminal coupled to the first segment of the second signal line and to the second segment of the second signal line; and
a fourth resistor terminal coupled to a ground connection of the circuit substrate.

19. The device of claim 18, wherein the signal lines are a differential pair of signal lines, wherein the first signal line is a positive signal line of the differential pair of signal lines, and the second signal line is a negative signal line of the differential pair of signal lines.

20. The device of claim 15, wherein the first signal line and the second signal line are floating signal lines in a floating state.

21. The device of claim 15, further comprising:
a first surface-mounted bond finger electrically coupled to the second segment of the first signal line and to the third die terminal for connecting the first signal line to the second die, the first surface-mounted bond finger being connected to the third die terminal by a first bond wire; and
a second surface-mounted bond finger electrically coupled to the second segment of the second signal line and to the fourth die terminal for connecting the second signal line to the second die, the second surface-mounted bond finger being connected to the fourth die terminal by a second bond wire.

22. The device of claim 21, wherein the first surface-mounted resistor and the second surface-mounted resistor are configured to reduce signal noise from the first surface-mounted bond finger and the second surface-mounted bond finger.

23. A device, comprising:
a circuit substrate comprising a plurality of signal traces that form a signal line;
a first die arranged on the circuit substrate, wherein the first die is coupled to the signal line;
a second die arranged on the circuit substrate, wherein the second die is coupled to the signal line; and
a first surface-mounted resistor arranged on the circuit substrate, wherein the first surface-mounted resistor is configured to provide a first jumper connection, between the first die and the second die, along the signal line; and
wherein the first surface-mounted resistor is a zero-ohm equivalent resistor,
wherein the first signal line is a floating signal line, and
wherein the first surface-mounted resistor is configured to reduce signal noise on the signal line.

24. The device of claim 23, further comprising:
a second signal line formed by the plurality of signal traces,
wherein the first signal line and the second signal line are a differential pair of signal lines, and
wherein the first die and the second die are coupled to the second signal line; and
a second surface-mounted resistor arranged on the circuit substrate, wherein the second surface-mounted resistor is configured to provide a second jumper connection, between the first die and the second die, along the second signal line,
wherein the second surface-mounted resistor is a zero-ohm equivalent resistor,
wherein the second signal line is a floating signal line, and
wherein the second surface-mounted resistor is configured to reduce signal noise on the second signal line.

25. The device of claim 23, further comprising:
a second signal line formed by the plurality of signal traces, wherein the first die and the second die are coupled to the second signal line,
wherein the first surface-mounted resistor comprises:
a first resistor terminal coupled to the first signal line for providing the first jumper connection; and
a second resistor terminal coupled to a positive supply connection of the circuit substrate, and
wherein the second surface-mounted resistor comprises:
a third resistor terminal coupled to the second signal line for providing the second jumper connection; and
a fourth resistor terminal coupled to a ground connection of the circuit substrate.

26. A method of manufacturing a device, the method comprising:
providing a circuit substrate comprising a plurality of signal traces that form a differential pair of signal lines, wherein the differential pair of signal lines includes a first differential signal line and a second differential signal line;
arranging a first die on the circuit substrate such that the first die is coupled to the differential pair of signal lines;
arranging a second die on the circuit substrate such that the second die is coupled to the differential pair of signal lines;
arranging a first surface-mounted resistor on the circuit substrate such that the first surface-mounted resistor provides a first jumper connection, between the first die and the second die, along the first differential signal line; and
arranging a second surface-mounted resistor on the circuit substrate such that the second surface-mounted resistor provides a second jumper connection, between the first die and the second die, along the second differential signal line,
wherein the first surface-mounted resistor and the second surface-mounted resistor are zero-ohm equivalent resistors,
wherein the first differential signal line and the second differential signal line are floating signal lines, and
wherein the first surface-mounted resistor and the second surface-mounted resistor are configured to reduce signal noise on the differential pair of signal lines.
